(19) United States
(12) Patent Application Publication
(10) Pub. No.: US 2025/0048534 A1
(43) Pub. Date: Feb. 6, 2025

(54) PRINTED CIRCUIT BOARD

(71) Applicant: SAMSUNG ELECTRO-MECHANICS CO., LTD., Suwon-si (KR)

(72) Inventors: Jin Uk LEE, Suwon-si (KR); Myong Keun JUNG, Suwon-si (KR); Young Hun YOU, Suwon-si (KR)

(73) Assignee: SAMSUNG ELECTRO-MECHANICS CO., LTD., Suwon-si (KR)

(21) Appl. No.: 18/666,110

(22) Filed: May 16, 2024

(30) Foreign Application Priority Data
Aug. 4, 2023 (KR) 10-2023-0102186

(51) Int. Cl. H05K 1/02; H05K 1/11

(52) U.S. Cl. CPC H05K 1/0224; H05K 1/0298; H05K 1/116

(57) ABSTRACT

The present disclosure relates to a printed circuit board, including: an interconnect bridge including an insulating material, a plurality of conductive pattern layers respectively disposed on or in the insulating material, and a conductive post disposed on the insulating material; a first insulating layer embedding the interconnect bridge and having a recess portion exposing a portion of the conductive post; and a first wiring layer disposed on the first insulating layer and including a first pad pattern connected to the exposed portion of the conductive post on the recess portion.

### CROSS-REFERENCE TO RELATED APPLICATION(S)

This application claims benefit of priority to Korean Patent Application No. 10-2023-0102186 filed on Aug. 4, 2023, in the Korean Intellectual Property Office, the disclosure of which is incorporated herein by reference in its entirety.

### TECHNICAL FIELD

The present disclosure relates to a printed circuit board.

As the number of CPU and GPU cores of a server product increases rapidly, a die split technology that may effectively increase the number of cores is becoming more common. In addition, as demand for packages including High Bandwidth Memory (HBM) increases, a technology for connecting die-to-die with a microcircuit line width is required. A technology using a silicon interposer has been developed to satisfy these technological demands, but there is a limit to commercialization due to pricing problems and complicated assembly processes. Furthermore, a technology for embedding a silicon bridge in a substrate has been developed, but there is a limit to implementing a high degree of matching when embedding a bridge due to bridge position deviation, via processing deviation, pad exposure deviation, etc.

### SUMMARY

An aspect of the present disclosure is to provide a printed circuit board that may improve a degree of matching when an interconnect bridge is built in.

Another aspect of the present disclosure is to provide a printed circuit board that may be manufactured through a process that has little effect on changes in a thickness of the interconnect bridge.

As one of the various solutions proposed in the present disclosure, a conductive post is raised high on an interconnect bridge and is covered with an insulating layer, and scribing and the like is performed on the insulating layer so that a portion of the conductive post is exposed, to form a recess portion, and then, a conductive pad connected to the conductive post is formed on the recess portion.

For example, according to an aspect of the present disclosure, a printed circuit board may include: an interconnect bridge including an insulating material, a plurality of conductive pattern layers respectively disposed on or in the insulating material, and a conductive post disposed on the insulating material; a first insulating layer embedding the interconnect bridge and having a recess portion exposing a portion of the conductive post; and a first wiring layer disposed on the first insulating layer and including a first pad pattern connected to the exposed portion of the conductive post on the recess portion.

For example, according to an aspect of the present disclosure, a printed circuit board may include: a first substrate unit including a plurality of first insulating layers, a plurality of first wiring layers disposed on or in the plurality of first insulating layers, and a plurality of first via layers respectively penetrating through at least one of the plurality of first insulating layers; and a second substrate unit including a plurality of second insulation layers, a plurality of second wiring layers disposed on or in the plurality of second insulation layers, a plurality of second via layers respectively penetrating through at least one of the plurality of second insulation layers, and a plurality of conductive posts respectively disposed on a second insulation layer disposed on an uppermost side, among the plurality of second insulation layers. The second substrate unit may be disposed in the first substrate unit, at least one of the plurality of second wiring layers may have a smaller average pitch of a wiring than at least one of the plurality of first wiring layers, and at least one of the plurality of first insulating layers may have a step region exposing a portion of each of the plurality of conductive posts.

For example, according to an aspect of the present disclosure, a printed circuit board may include: an interconnect bridge including an insulating material, a plurality of conductive pattern layers respectively disposed on or in the insulating material, and a conductive post disposed on an upper surface of the insulating material; a first insulating layer embedding the interconnect bridge and being in contact with at least a portion of the upper surface of the insulating material; a first wiring layer disposed on the first insulating layer and including a first pad pattern to be in contact with the conductive post; a second wiring layer disposed in the first insulating layer; and a first via layer penetrating through the first insulating layer and connecting the first and second wiring layers.

One effect of the present disclosure is to provide a printed circuit board that may improve a degree of matching when an interconnect bridge is built in.

Another effect of the present disclosure is to provide a printed circuit board that may be manufactured through a process that has little effect on changes in a thickness of the interconnect bridge.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating a case in which a BGA package is mounted on a main board of an electronic device;

FIG. 4 is a cross-sectional view schematically illustrating a case in which a silicon interposer package is mounted on a main board;

FIG. 5 is a cross-sectional view schematically illustrating a case in which an organic interposer package is mounted on a main board;

FIG. 6 is a cross-sectional view schematically illustrating an example of a printed circuit board;

FIG. 7 is a schematic cross-sectional view illustrating an example of an interconnect bridge;

FIG. 8A is an enlarged cross-sectional view schematically illustrating an example of region A of FIG. 6;

FIG. 8B is an enlarged cross-sectional view schematically illustrating another example of region A of FIG. 6;

FIGS. 9A to 9H are process views schematically illustrating an example of manufacturing a printed circuit board;

FIG. 10 is a cross-sectional view schematically illustrating a modified example of a printed circuit board;

FIG. 11 is a cross-sectional view schematically illustrating another example of a printed circuit board;

FIG. 12 is a schematic cross-sectional view of another example of an interconnect bridge;

FIG. 13 is a cross-sectional view schematically illustrating another example of a printed circuit board;

FIG. 14 is a schematic cross-sectional view of another example of an interconnect bridge;

FIG. 15 is a cross-sectional view schematically illustrating another example of a printed circuit board;

FIG. 16 is a schematic cross-sectional view of another example of an interconnect bridge;

FIG. 17 is a cross-sectional view schematically illustrating another example of a printed circuit board;

FIG. 18 is a schematic cross-sectional view of another example of an interconnect bridge;

FIG. 19 is a schematic cross-sectional view of another example of a printed circuit board;

FIG. 20 is a schematic cross-sectional view of another example of an interconnect bridge;

FIG. 21 is a cross-sectional view schematically illustrating another example of a printed circuit board; and

FIG. 22 is a schematic cross-sectional view of another example of an interconnect bridge.

### DETAILED DESCRIPTION

Hereinafter, the present disclosure will be described with reference to the accompanying drawings. In the drawings, the shape and size of the elements may be exaggerated or reduced for clearer description.

### Electronic Device

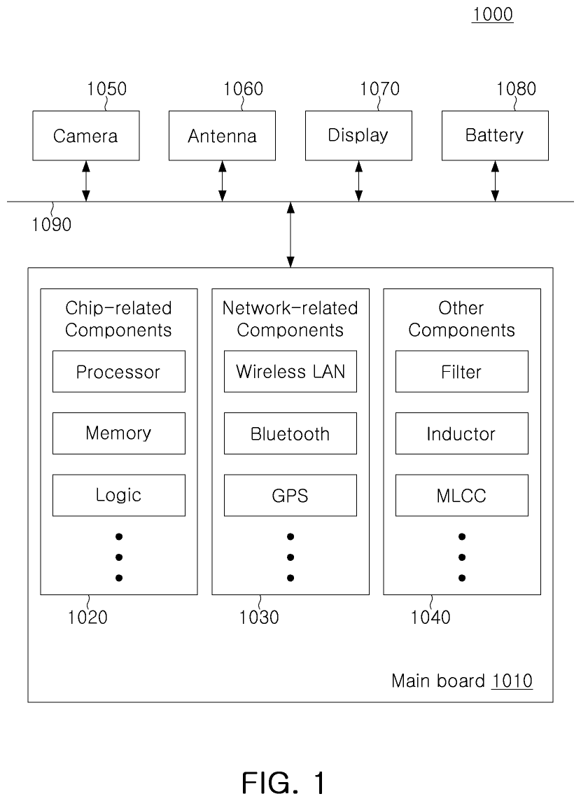

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

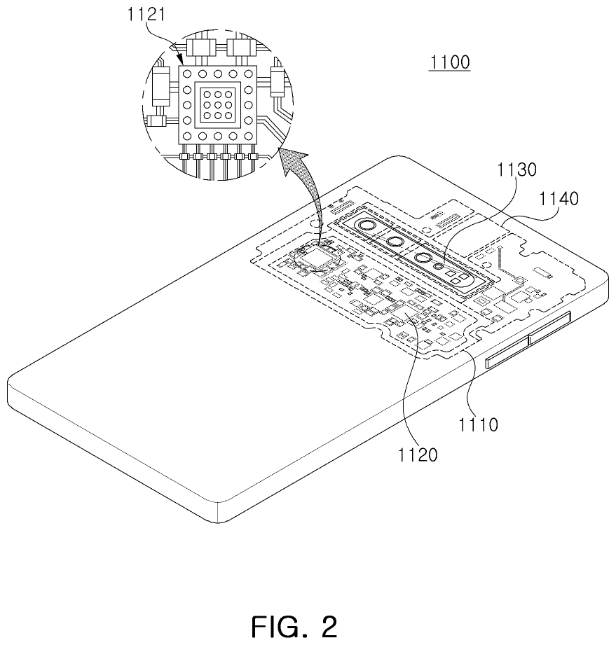

FIG. 2 is a perspective view schematically illustrating an example of an electronic device.

Referring to FIG. 2, an electronic device may be, for example, a smartphone 1100. A mother board 1110 may be accommodated in the smartphone 1100, and various components 1120 may be physically and/or electrically connected to the mother board 1110. Furthermore, other components that may or may not be physically and/or electrically connected to the mother board 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may have the form of a printed circuit board in which an electronic component including an active component and/or a passive component is mounted on a surface.

Alternatively, the component package 1121 may have the form of a printed circuit board in which an active component and/or a passive component are embedded. On the other hand, the electronic device is not necessarily limited to the smartphone 1100, and may be other electronic devices as described above.

### Semiconductor Package Including Interposer

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than a scale of the semiconductor chip. Therefore, it may be difficult to directly mount the semiconductor chip on the mainboard, and packaging technology for buffering a difference in a circuit width between the semiconductor chip and the mainboard is required.

Hereinafter, a semiconductor package including an interposer manufactured using this packaging technology will be described in more detail with reference to the drawings.

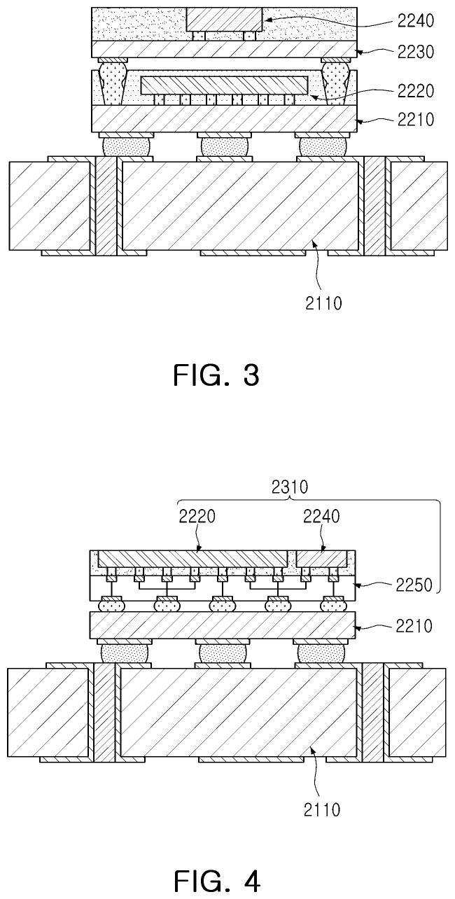

FIG. 3 is a cross-sectional view schematically illustrating a case in which a BGA package is mounted on a main board of an electronic device.

Among semiconductor chips, each chip provided in an application specific integrated circuit, such as a graphics processing unit (GPU), is significantly expensive, and thus, it may be necessary to perform a packaging in high yield. To this end, a ball grid array (BGA) substrate 2210, capable of redistributing several thousands or several millions of connection pads, may be prepared before mounting a semiconductor ship, and an expensive semiconductor chip, such as a GPU 2220, may be mounted on the BGA substrate 2210 by surface mounting technology (SMT) and packaged, and then mounted on a mainboard 2110. Meanwhile, the BGA substrate 2210 may include a flip chip BGA (FCBGA) substrate.

Meanwhile, in the case of the GPU 2220, it may be necessary to significantly reduce a signal path to a memory, such as a high bandwidth memory (HBM), and to this end, generally, a semiconductor chip, such as an HBM 2220, is mounted on an interposer 2230 and packaged, and the semiconductor is stacked and used in a form of package-on-package on the package on which the GPU 2220 is mounted. However, in this case, a thickness of a device may significantly increase, and there may be a limitation in reducing a signal path.

FIG. 4 is a cross-sectional view schematically illustrating a case in which a silicon interposer package is mounted on a main board.

To address the aforementioned issue, a semiconductor package 2310 including a silicon interposer may be manufactured using an interposer technique of mounting a first semiconductor chip such as a GPU 2220 and a second semiconductor chip such as an HBM 2240 side by side on a surface of a silicon interposer 2250 and packaging the semiconductor chips. In this case, the GPU 2220 and the HBM 2240 having several thousands or several millions of connection pads may be redistributed by the interposer 2250, and further, the GPU 2220 and the HBM 2240 may be electrically connected to each other by a significantly reduced path. Additionally, in the case in which the semiconductor package 2310 including the silicon interposer is mounted on a BGA substrate 2210, and the like, again and redistributed, the semiconductor package may be mounted on a mainboard 2110.

However, in the case of the silicon interposer 2250, it may be difficult to form a through-silicon via (TSV), and manufacturing costs of the silicon interposer are also high, and accordingly, it may be difficult to implement a semiconductor package having a large area at low cost.

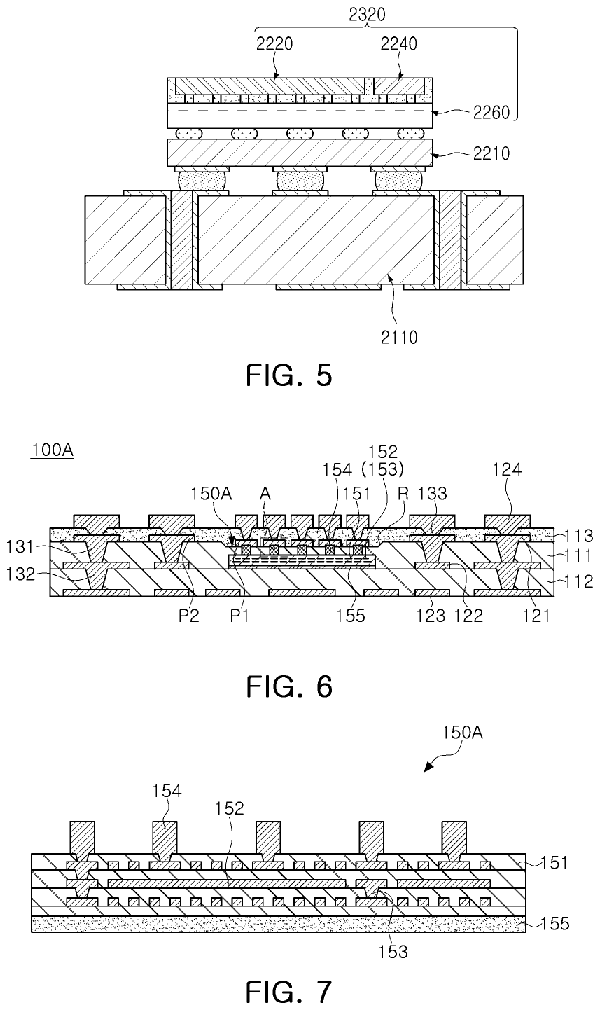

FIG. 5 is a cross-sectional view schematically illustrating a case in which an organic interposer package is mounted on a main board.

To address the aforementioned issue, an organic interposer 2260 may be used instead of a silicon interposer 2250. For example, a semiconductor package 2320 including an organic interposer may be manufactured using an interposer technique of mounting a first semiconductor chip such as a GPU 2220 and a second semiconductor chip such as an HBM 2240 side by side on a surface of the organic interposer 2260 and packaging the semiconductor chips. In this case, it may be possible to redistribute the GPU 2220 and the HBM 2240 having several thousands or several millions of connection pads through the organic interposer 2260, and further, the GPU 2220 and the HBM 2240 may be electrically connected to each other by a significantly reduced path. Furthermore, by remounting the semiconductor package 2310 including the organic interposer again on a BGA substrate 2210, and the like, and redistributing the semiconductor package, the semiconductor package may be mounted on a mainboard 2110. Accordingly, it may be possible to implement a semiconductor package having a large area at low cost.

However, when using the organic interposer 2260, semiconductor chips 2220 and 2240 must also be mounted on the organic interposer 2260 and then mounted on the BGA substrate 2210, and thus, a process thereof may be somewhat complicated and packaging yield may be lowered.

Printed Circuit Board with Built-In Bridge

FIG. 6 is a cross-sectional view schematically illustrating an example of a printed circuit board.

FIG. 7 is a schematic cross-sectional view illustrating an example of an interconnect bridge.

Referring to the drawings, a printed circuit board 100A according to one example embodiment may include an interconnect bridge 150A including an insulating material 151, a plurality of conductive pattern layers 152 disposed in the insulating material 151, and a conductive post 154 disposed on the insulating material 151, a first insulating layer 111 embedding the interconnect bridge 150A and having a recess portion R exposing a portion of the conductive post 154, and a first wiring layer 121 disposed on the first insulating layer 111 and including a first pad pattern P1 connected to an exposed portion of the conductive post 154 on the recess portion R. Here, exposure of the conductive post 154 may be determined based on the first insulating layer 111. For example, the exposure may refer to being exposed from the first insulating layer 111. If necessary, the first wiring layer 121 may further include a second pad pattern P2 disposed in a region other than the recess portion R and spaced apart from the conductive post 154.

As described above, in the printed circuit board 100A according to an example embodiment, the interconnect bridge 150A may include a conductive post 154 that is relatively narrower and higher in height as compared to a general pad, and as the first pad pattern P1 connected thereto may be relatively wider, sufficient exposure tolerance and/or alignment tolerance may be secured. Furthermore, after embedding the interconnect bridge 150A, the conductive post 154 may be directly connected to the first pad pattern P1 without via processing, which may be more advantageous to improve a degree of matching. Furthermore, since a portion of the conductive post 154 may be exposed through the recess portion R, the above-described structure and effects thereof may be more easily implemented, and may have little effect on changes in thicknesses of the first insulating layer 111 and/or the interconnect bridge 150A. Accordingly, a process window may be wider and may be more advantageous for mass production. Additionally, the difficulty of the manufacturing process may be reduced.

If necessary, the printed circuit board 100A according to one example embodiment may further include a second wiring layer 122 disposed in the first insulating layer 111, a first via layer 131 penetrating through the first insulating layer 111 and connecting the first and second wiring layers 121 and 122, a second insulating layer 112 disposed below the first insulating layer 111, a third wiring layer 123 disposed in the second insulating layer 112, a second via layer 132 penetrating through the second insulating layer 112 and connecting the second and third wiring layers 122 and 123, a third insulating layer 113 disposed on the first insulating layer 111 and covering the first wiring layer 121, a fourth wiring layer 124 disposed on the third insulating layer 113, and include a third via layer 133 penetrating through the third insulating layer 113 and connecting the first and fourth wiring layers 121 and 124.

In this manner, the printed circuit board 100A may have an Embedded Trace Substrate (ETS) structure. However, the present disclosure is not limited thereto, and the printed circuit board 100A may be a core-type board including a core insulating layer. For example, a portion illustrated in the drawing may represent a built-up upper portion of a core-type substrate. The printed circuit board 100A may be a BGA board or an FCBGA board, but the present disclosure is not limited thereto.

Meanwhile, the recess portion R may be tapered so that a width of an upper portion thereof is greater than a width of a lower portion on a cross-section. An upper surface of the first insulating layer 111 may have a step portion due to the recess portion R. For example, the first insulating layer 111 may have a step region due to the recess portion R. The first pad pattern P1 may be disposed in the step region, and the second pad pattern P2 may be disposed outside the step region, and thus, upper surfaces and lower surfaces of each of the first and second pad patterns P1 and P2 may have a step portion from each other. Meanwhile, the step portion of the first insulating layer 111 due to the recess portion R may be recovered through the third insulating layer 113. For example, an upper surface of the third insulating layer 113 may be substantially flat.

Hereinafter, components of the printed circuit board 100A according to an example will be described in more detail with reference to the drawings.

Each of the first to third insulating layers 111, 112 and 113 may include an insulating material. As an insulating material, a thermosetting resin such as an epoxy resin, a thermoplastic resin such as polyimide, or a material in which these regions are mixed with an inorganic filler such as silica, or a resin impregnated into a core material such as glass fiber (Glass Fiber, Glass Cloth or Glass Fabric) together with the inorganic filler, for example, organic insulating materials such as Ajinomoto Build-up Film (ABF), Prepreg and the like, may be used, but the present disclosure is not limited thereto. As a non-limiting example, the first to third insulating layers 111, 112 and 113 may include substantially the same material, but the present disclosure is not limited thereto. Here, substantially the same material may be an insulating material with the same brand name. Solder resist may be used as a material for the third insulating layer 113. For example, the third insulating layer 113 may be a solder resist layer.

Each of the first to fourth wiring layers 121, 122, 123 and 124 may include a metallic material. As the metallic material, copper (Cu), aluminum (Al), silver (Ag), tin (Sn), gold (Au), nickel (Ni), lead (Pb), titanium (Ti), or alloys thereof may be used. Each of the first to fourth wiring layers 121, 122, 123 and 124 may include an electroless plating layer (or chemical copper) and/or an electrolytic plating layer (or electrolytic copper). If necessary, the first to fourth wiring layers 121, 122, 123 and 124 may include a sputtering layer. If necessary, the first to fourth wiring layers 121, 122, 123 and 124 may include copper foil. The first to fourth wiring layers 121, 122, 123 and 124 may perform various functions depending on the design of each corresponding layer. For example, the first to fourth wiring layers 121, 122, 123 and 124 may include a ground pattern, a power pattern, and a signal pattern. Here, the signal pattern may include various signals other than the ground pattern, the power pattern, and the like, for example, a data signal. These patterns may each include a line pattern, a plane pattern, and/or a pad pattern. For example, the first wiring layer 121 may include first and second pad patterns P1 and P2.

Each of the first to third via layers 131, 132 and 133 may include a metallic material. As the metal material, copper (Cu), aluminum (Al), silver (Ag), tin (Sn), gold (Au), nickel (Ni), lead (Pb), titanium (Ti), or alloys thereof may be used. Each of the first to third via layers 131, 132 and 133 may include an electroless plating layer (or chemical copper) and/or an electrolytic plating layer (or electrolytic copper). If necessary, the first to third via layers 131, 132 and 133 may include a sputtering layer. Each of the first to third via layers 131, 132 and 133 may have a filled type in which a via hole is filled with a metallic material, but is not limited thereto, and may be a conformal type in which a metallic material is disposed along a wall of the via hole. Each of the first to third via layers 131, 132 and 133 may have a tapered shape in which an upper end thereof is wider than a lower end thereof on a cross-section. Each of the first to third via layers 131, 132 and 133 may perform various functions depending on the design of each corresponding layer. For example, the first to third via layers 131, 132 and 133 may include a ground via, a power via, and a signal via. Here, the signal via may include vias for transmitting various signals excluding the ground via, the power via, and the like, for example, a data signal, and the like. The first to third via layers 131, 132 and 133 may include a stacked via and/or a staggered via depending on upper and lower connection types.

The interconnect bridge 150A may be a silicon bridge manufactured by utilizing silicon dioxide as an insulating body and forming a wiring through a deposition process, or may be an organic bridge manufactured by utilizing an organic insulating material as an insulating body and forming a wiring through a plating process. The interconnect bridge 150A may be, preferably, the organic bridge, and in this case, reliability problems due to CTE mismatch may rarely occur. Additionally, the process difficulty and cost for manufacturing the interconnect bridge 150A may be reduced. Additionally, the interconnect bridge 150A may have an ETS structure, such as a coreless substrate structure. In this manner, when the interconnect bridge 150A is formed in the form of a coreless substrate, it may be possible to implement a wiring design with a finer pitch. Additionally, the interconnect bridge 150A may be manufactured at a lower cost than a silicon bridge, and a process thereof may be simpler. The organic bridge may be a high-density circuit board.

The insulating material 151 may include an insulating material. The insulating material may be an organic insulating material such as a photosensitive insulating material PID. When using the photosensitive insulating material PID as a material for the insulating material 151, a thickness of the insulating material 151 may be minimized, and a photo via hole may be formed, and thus, a plurality of conductive pattern layers 152 may be designed with high density. However, the material is not limited thereto, and other organic insulating materials such as ABF may be used. If necessary, an inorganic insulating material such as silicon may be included. The insulating material 151 may be comprised of a plurality of insulating layers, and the number of layers is not particularly limited. Boundaries between the plurality of insulating layers may be distinct from each other or may be unclear.

A plurality of conductive pattern layers 152 may provide a die-to-die wiring path. The plurality of conductive pattern layers 152 may be comprised of a plurality of layers, and the number of layers is not particularly limited. The plurality of conductive pattern layers 152 may perform various functions depending on the design of the corresponding layer, and may include at least a signal pattern. Each of the plurality of conductive pattern layers 152 may include a line pattern, a plane pattern, and/or a pad pattern. Each of the plurality of conductive pattern layers 152 may include a metallic material such as copper (Cu), aluminum (Al), silver (Ag), tin (Sn), gold (Au), nickel (Ni), lead (Pb), titanium (Ti), or alloys thereof. Each of the plurality of conductive pattern layers 152 may include an electroless plating layer (or chemical copper) and/or an electrolytic plating layer (or electrolytic copper). If necessary, the plurality of conductive pattern layers 152 may include a sputtering layer.

The plurality of conductive pattern layers 152 may have a higher circuit density than the first to fourth wiring layers 121, 122, 123 and 124. That is, the plurality of conductive pattern layers 152 may include a higher density circuit. For example, an average pitch of a wiring included in at least one of the plurality of conductive pattern layers 152 may be smaller than the average pitch of a wiring included in at least one of the first to fourth wiring layers 121, 122, 123 and 124. Additionally, an average interlayer insulation distance between the plurality of conductive pattern layers 152 may be smaller than an average interlayer insulation distance between the first to fourth wiring layers 121, 122, 123 and 124.

The plurality of conductive pattern layers 152 may have two high-density wiring layers and one ground layer, and a line pattern for signal transmission may be omitted in the ground layer, but the present disclosure is not limited thereto. The high-density wiring layer may have only one design rule, such as a line/space, for example, L/S of 2 μm/2 μm or 1 μm/1 μm, but the present disclosure is not limited thereto.

The plurality of conductive pattern layers 152 may be electrically connected to each other through the plurality of conductive via layers 153. Each of the plurality of conductive via layers 153 may include a metallic material such as copper (Cu), aluminum (Al), silver (Ag), tin (Sn), gold (Au), nickel (Ni), lead (Pb), titanium (Ti), or alloys thereof. Each of the plurality of conductive via layers 153 may include an electroless plating layer (or chemical copper) and/or an electrolytic plating layer (or electrolytic copper). If necessary, the plurality of conductive via layers 153 may include a sputtering layer. Each of the plurality of conductive via layers 153 may have a filled type in which a via hole is filled with a metallic material, but is not limited thereto, and may be a conformal type in which a metallic material is disposed along a wall of the via hole. Each of the plurality of conductive via layers 153 may have a tapered shape in which an upper end thereof is wider than a lower end thereof in a cross-section. Each of the plurality of conductive via layers 153 may perform various functions depending on the design of each corresponding layer. For example, the plurality of conductive via layers 153 may include a ground via, a power via, and a signal via. Here, the signal via may include vias for transmitting various signals excluding the ground via, the power via, and the like, for example, a data signal, and the like. The plurality of conductive via layers 153 may include a stacked via and/or a staggered via depending on upper and lower connection types.

The conductive post 154 may have a high aspect ratio. For example, the aspect ratio may exceed 1. The conductive post 154 may perform various functions such as a signal post, a ground post, a power post, and the like. The conductive post 154 may include at least a signaling post. The conductive post 154 may include a metallic material such as copper (Cu), aluminum (Al), silver (Ag), tin (Sn), gold (Au), nickel (Ni), lead (Pb), titanium (Ti), or alloys thereof. The conductive post 154 may be formed in a plating process, and may include an electroless plating layer (or chemical copper) and an electrolytic plating layer (or electrolytic copper), but the present disclosure is not limited thereto. If necessary, the conductive post 154 may include a sputtering layer. The conductive post 154 may be connected to a conductive pattern layer 152 disposed on an uppermost side, among the plurality of conductive via layers 153, through a conductive via layer 153 disposed on an uppermost side, among the plurality of conductive via layers 153. The conductive post 154 may be provided in plural form.

The interconnect bridge 150A may be attached to an upper surface of the second insulating layer 112 through an adhesive 155. The adhesive 155 may include a known adhesive material, such as an epoxy-based adhesive material, but the material is not particularly limited thereto.

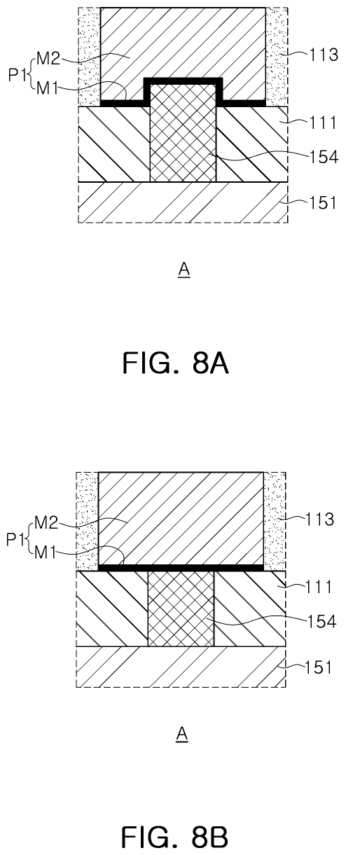

FIG. 8A is an enlarged cross-sectional view schematically illustrating an example of region A of FIG. 6.

Referring to FIG. 8A, the conductive post 154 may formed so that one portion thereof is embedded in the first insulating layer 111, and the other portion thereof may protrude onto the first insulating layer 111. For example, an upper surface of the conductive post 154 may have a step portion from an upper surface of the first insulating layer 111. In this case, a contact area with the first pad pattern P1 may increase, thus allowing for better adhesion. The first pad pattern P1 may be disposed on the upper surface of the first insulating layer 111 in the recess portion R and may cover another protruding portion of the conductive post 154. The first pad pattern P1 may include a first metal layer M1 covering the upper surface of the first insulating layer 111 and an upper surface and a side surface of another protruding portion of the conductive post 154 with a substantially constant thickness, and a second metal layer M2 disposed on the first metal layer M1, in which an average thickness thereof is thicker than that of the first metal layer M1. The first metal layer M1 may be a seed layer formed through electroless plating and/or sputtering. The second metal layer M2 may be a plating layer formed through electrolytic plating.

FIG. 8B is an enlarged cross-sectional view schematically illustrating another example of region A of FIG. 6.

Referring to FIG. 8B, the conductive post 154 may be embedded in the first insulating layer 111 and an upper surface thereof may be exposed from the upper surface of the first insulating layer 111. For example, the upper surface of the conductive post 154 may be substantially coplanar with the upper surface of the first insulating layer 111.

In this case, the conductive post 154 may provide a flatter surface. The first pad pattern P1 may be disposed on the upper surface of the first insulating layer 111 on the recess portion R and may cover an exposed upper surface of the conductive post 154. The first pad pattern P1 may include a first metal layer M1 covering the upper surface of the first insulating layer 111 and the exposed upper surface of the conductive post 154 with a substantially constant thickness, and a second metal layer M2 disposed on the first metal layer M1 in which an average thickness thereof is thicker than that of the first metal layer M1. The first metal layer M1 may be a seed layer formed through electroless plating and/or sputtering. The second metal layer M2 may be a plating layer formed through electrolytic plating.

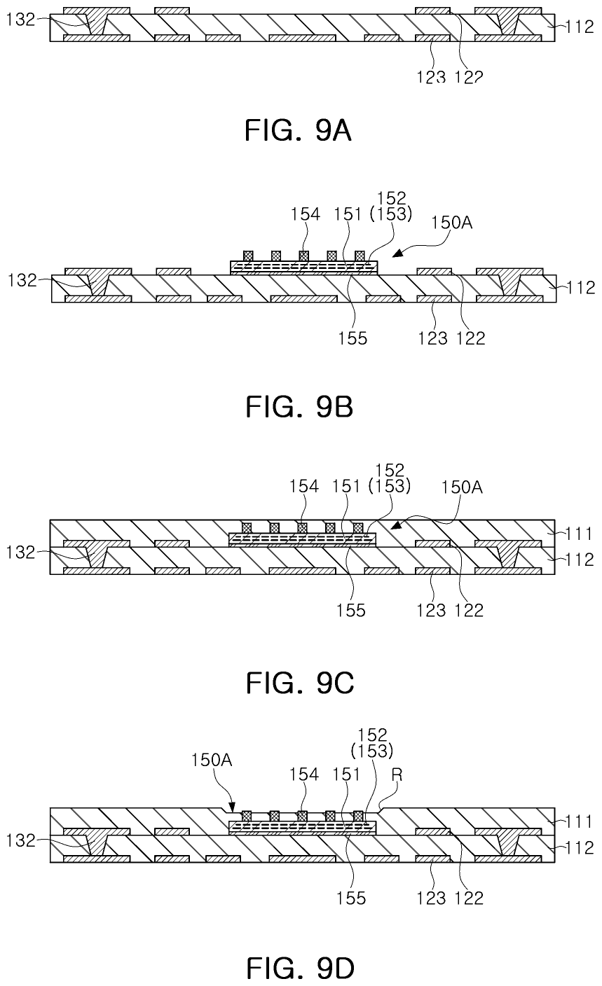

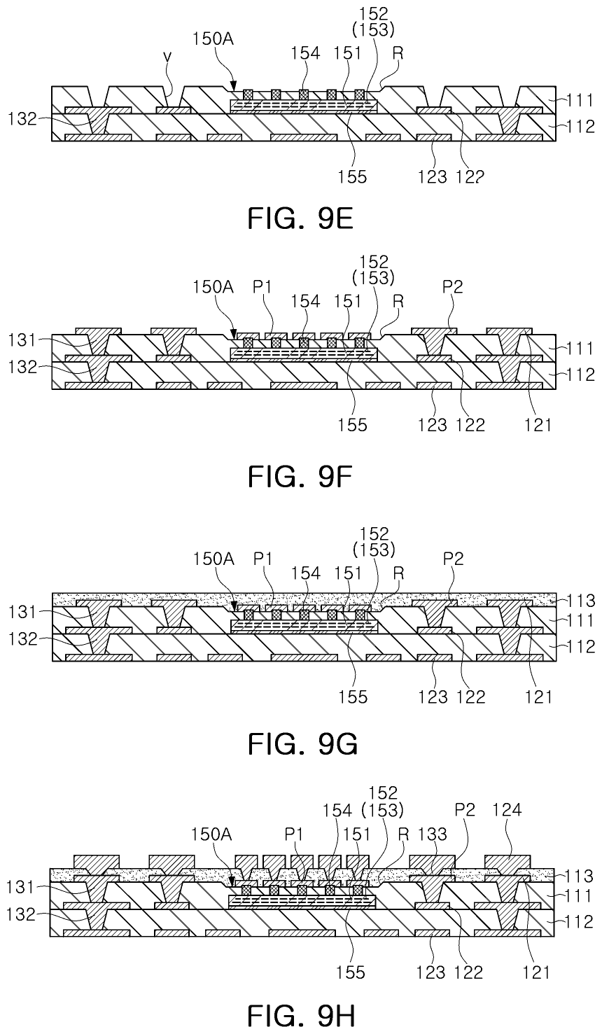

FIGS. 9A to 9H are process views schematically illustrating an example of manufacturing a printed circuit board.

Referring to FIG. 9A, a second insulating layer 112, second and third wiring layers 122 and 123, and a second via layer 132 are formed through a build-up process using a carrier substrate. A via hole for forming the second via layer 132 may be formed using laser processing, mechanical drilling, or the like. The second and third wiring layers 122 and 123 and the second via layer 132 may be formed through a circuit formation process such as Additive Process (AP), Semi AP (SAP), Modified SAP (MSAP), and Tenting (TT). The second insulating layer 112 may be formed through a lamination process such as ABF.

Referring to FIG. 9B, the interconnect bridge 150A is attached using the adhesive 155. The interconnect bridge 150A may be manufactured through a substrate process. For example, the interconnect bridge 150A may be manufactured by forming a plurality of conductive pattern layers 152 and a plurality of conductive via layers 153 on the insulating material 151 in a build-up process using a carrier substrate, and then forming a plurality of conductive posts 154 on the insulating material 151 in a plating process using a resist. Among the plurality of conductive via layers 153, a conductive via layer 153 on an uppermost side may be formed together therewith when forming a plurality of conductive posts 154.

Referring to FIG. 9C, the first insulating layer 111 is stacked on the second insulating layer 112 to embed the interconnect bridge 150A. The first insulating layer 111 may be formed, for example, in a process of performing lamination on ABF or the like on the second insulating layer 112.

Referring to FIG. 9D, a recess portion R exposing a portion of the conductive post 154 is formed in the first insulating layer 111. The recess portion R may be formed in a partial skiving process or a partial thinning process. Plasma etching, wet etching, dry etching, laser processing, blast processing, or the like, may be used in the skiving process or the thinning process. A step region may be formed on an upper side of the first insulating layer 111 by the recess portion R.

Referring to FIG. 9E, a via hole v is formed in the first insulating layer 111. The via hole v may be formed using laser processing, mechanical drilling, or the like.

Referring to FIG. 9F, a first wiring layer 121 including first and second pad patterns P1 and P2 is formed on the first insulating layer 111. Additionally, a first via layer 131 is formed in the via hole v. The first wiring layer 121 and the first via layer 131 may be formed using a circuit forming process such as AP, SAP, MSAP, TT, or the like. The first pad pattern P1 may cover the exposed conductive post 154 and be connected thereto.

Referring to FIG. 9G, the third insulating layer 113 is stacked on the first insulating layer 111. A step portion may be recovered through the third insulating layer 113. The third insulating layer 113 may be formed, for example, in a process of performing lamination on ABF or SR on the first insulating layer 111. Alternatively, the third insulating layer 113 may be formed in a process of applying and curing an SR material.

Referring to FIG. 9H, a fourth wiring layer 124 and a third via layer 133 are formed on the third insulating layer 113. A via hole for forming the third via layer 133 may be formed using laser processing, mechanical drilling, or the like. The fourth wiring layer 124 and the third via layer 133 may be formed using a circuit forming process such as AP, SAP, MSAP, or TT. The printed circuit board 100A according to the aforementioned example embodiment may be manufactured through a series of processes.

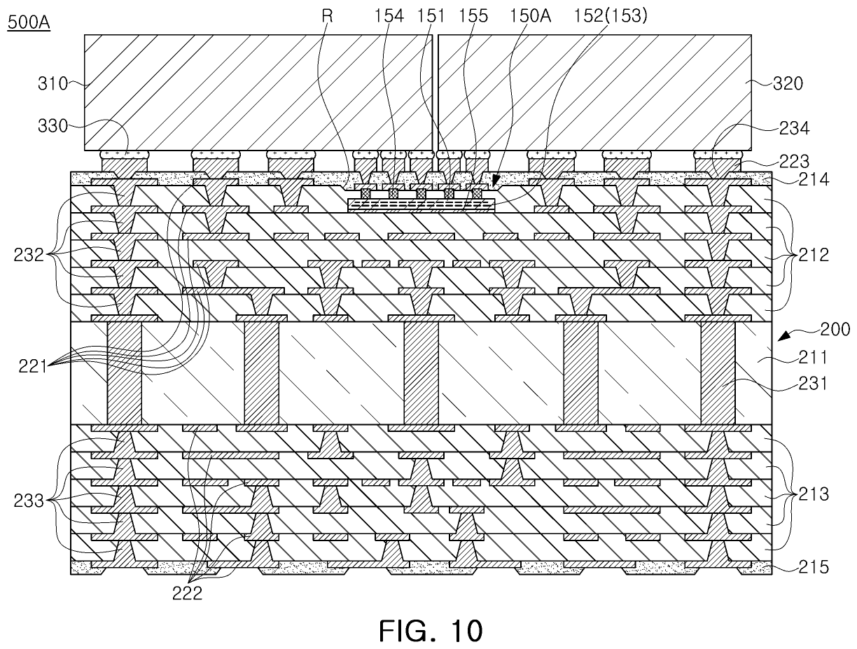

FIG. 10 is a cross-sectional view schematically illustrating a modified example of a printed circuit board.

Referring to FIG. 10, a printed circuit board 500A according to a modified example may include a first substrate unit 200, a second substrate unit 150A disposed in the first substrate 200, and first and second semiconductor chips 310 and 320 respectively disposed on the first substrate 200 and connected to each other through the second substrate 150A. The first substrate 200 may be a multilayer core substrate, and may include a plurality of first insulating layers 211, 212, 213, 214 and 215, a plurality of first wiring layers 221, 222 and 223, and a plurality of first via layers 231, 232 and 233. The second substrate portion 150A may be the interconnect bridge 150A described above, and may include a plurality of second insulating layers 151, a plurality of second wiring layers 152, a plurality of second via layers 153, and a plurality of conductive posts 154. The second substrate portion 150A may be attached to the first substrate unit 200 through an adhesive 155. The printed circuit board 100A according to the aforementioned example embodiment may be partially applied to the printed circuit board 500A according to a modified example. For example, the printed circuit board 500A according to the modified example may include the printed circuit board 100A according to the aforementioned example embodiment as a portion of the package substrate, for example, as a portion of an upper build-up region in a core-type substrate, and may be in the form of a semiconductor package on which the first and second semiconductor chips 310 and 320 are mounted.

Each of the plurality of first insulating layers 211, 212, 213, 214 and 215 may include an insulating material. As the insulating material, a thermosetting resin such as an epoxy resin, a thermoplastic resin such as polyimide, or a material in which these resins are mixed with an inorganic filler such as silica, or a resin impregnated into a core material such as glass fiber (glass fiber, glass cloth or glass fabric) with the inorganic filler, for example, organic insulating materials such as Copper Clad Laminate (CCL), Ajinomoto Build-up Film (ABF), Prepreg and the like, may be used, but the present disclosure is not limited thereto. As a non-limiting example, a first-first insulating layer 211 may include CCL as a core layer, and a plurality of first-second insulating layers 212 and a plurality of first-second insulating layers 213 may include ABF or prepreg as a build-up layer, but the present disclosure is not limited thereto. A first-fourth insulating layer 214 and a first-fifth insulating layer 215 may include ABF or a solder resist as an outermost layer, but the present disclosure is not limited thereto. The first-first insulating layer 211 may include an insulating material other than an organic insulating material, such as a glass plate, if necessary.

Each of the plurality of first wiring layers 221, 222 and 223 may include a metallic material. As the metallic materials, copper (Cu), aluminum (Al), silver (Ag), tin (Sn), gold (Au), nickel (Ni), lead (Pb), titanium (Ti), or alloys thereof may be used. Each of the plurality of first wiring layers 221, 222 and 223 may include an electroless plating layer (or chemical copper) and an electrolytic plating layer (or electrical copper), but the present disclosure is not limited thereto. As an electroless plating layer, a sputter layer may be formed instead of chemical copper, and the plurality of first wiring layers 221, 222 and 223 may include both the sputter layer and the chemical copper. If necessary, the chemical copper may further include copper foil. The plurality of first wiring layers 221, 222 and 223 may perform various functions depending on the design of each corresponding layer. For example, the plurality of first wiring layers 221, 222 and 223 may include a ground pattern, a power pattern, and a signal pattern. These patterns may include a line pattern, a plane pattern, and/or a pad pattern, respectively.

Each of the plurality of first via layers 231, 232 and 233 may include a metallic material. As the metallic material, copper (Cu), aluminum (Al), silver (Ag), tin (Sn), gold (Au), nickel (Ni), lead (Pb), titanium (Ti), or alloys thereof may be used. Each of the plurality of first via layers 231, 232 and 233 may perform various functions depending on the design. For example, the plurality of first via layers 231, 232 and 233 may include a ground via, a power via, and a signal via. Each of the plurality of first via layers 231, 232 and 233 may include an electroless plating layer (or chemical copper) and an electrolytic plating layer (or electrolytic copper), but the present disclosure is not limited thereto. As the electroless plating layer, a sputter layer may be formed instead of chemical copper, and the plurality of first via layers 231, 232 and 233 may include both the sputtering layer and the chemical copper. A first-first via layer 231 may include a through-via. The through-via may include a metal layer formed on a wall surface of the through-hole and a plug filling the metal layer. The through-via may have a cylindrical shape, but is not limited thereto, and may also have an hourglass shape. Each of a plurality of first-second via layers 232 and a plurality of first-third via layers 233 may include a micro via. The micro via may be a filled via filling the via hole or a conformal vias disposed along the wall surface of the via hole. The micro via may be arranged in a stack type and/or a staggered type. The micro via may have a tapered shape. The micro vias of each of the plurality of first-second via layers 232 and the plurality of first-third via layers 233 may have a shape tapered in opposite directions.

Each of the first and second semiconductor chips 310 and 320 may include an integrated circuit (IC) die in which several hundreds to several millions of elements are integrated into one chip. In this case, the integrated circuit may be a logic chip such as a central processor (e.g., CPU), a graphics processor (e.g., GPU), a field programmable gate array (FPGA), a digital signal processor, a cryptographic processor, a microprocessor, a microcontroller, an application processor (e.g., AP), an analog-to-digital converter, or an application-specific IC (ASIC), but the present disclosure is not limited thereto, and the integrated circuit may be a memory chip such as a volatile memory (e.g., DRAM), a non-volatile memory (e.g., ROM), a flash memory, and a High Bandwidth Memory (HBM), or may be a different type such as a Power Management IC (PMIC). For example, the first semiconductor chip 310 may include a logic chip such as GPU, and the second semiconductor chip 320 may include a memory chip such as HBM. Alternatively, the first and second semiconductor chips 310 and 320 may be divided logic chips divided by die splitting and having different cores. However, the present disclosure is not limited thereto.

Each of the first and second semiconductor chips 310 and 320 may be formed based on an active wafer. In this case, as a base material forming each body, silicon (Si), germanium (Ge), gallium arsenide (GaAs), may be used. Various circuits may be formed in the body. A connection pad may be formed on each body, and the connection pad may include a conductive material such as aluminum (Al) or copper (Cu). The first and second semiconductor chips 310 and 320 may be bare dies, and in this case, metal bumps may be disposed on the connection pads. The first and second semiconductor chips 310 and 320 may be packaged dies, in which case a redistributing layer may be additionally formed on the connection pad, and metal bumps may be disposed on the redistributing layer. However, the present disclosure is not limited thereto.

The first and second semiconductor chips 310 and 320 may be connected to a first-third wiring layer 223 through a plurality of bumps 330. Each of the plurality of bumps 330 may be formed of a low melting point metal, for example, solder such as tin (Sn)-aluminum (Al)-copper (Cu), but this is only an example and a material thereof is specifically limited thereto. Each of the plurality of bumps 330 may be formed in a multilayer or a single layer. When the plurality of bumps 330 are formed in a multiple layer, the plurality of bumps 330 may include a copper pillar and a solder, and when the plurality of bumps 330 are formed in a single layer, the plurality of bumps 330 may include a tin-silver solder or copper, but the present disclosure is also not limited thereto.

Other contents are substantially the same as described above, and redundant description thereof will be omitted.

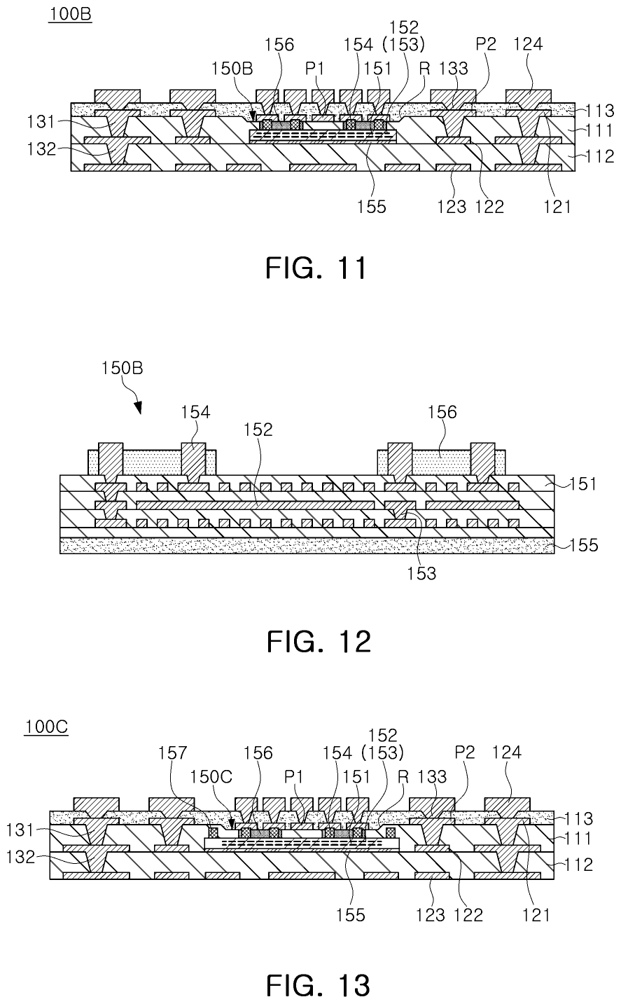

FIG. 11 is a cross-sectional view schematically illustrating another example of a printed circuit board.

FIG. 12 is a schematic cross-sectional view of another example of an interconnect bridge.

Referring to the drawings, a printed circuit board 100B according to another example embodiment and an interconnect bridge 150B included therein according to another example embodiment may further include a protective material 156, in the printed circuit board 100A according to the above-described example embodiment and the interconnect bridge 150A included therein according to the example embodiment. For example, the interconnect bridge 150B may further include the protective material 156 disposed on the insulating material 151 and covering at least one of the plurality of conductive posts 154. The protective material 156 may be disposed in a partial region on an upper surface of the insulating material 151. The protective material 156 may surround a side surface of at least one of the plurality of conductive posts 154 and expose a portion of an upper end of the conductive post 154. The protective material 156 may be formed to completely cover the corresponding conductive post 151 before the interconnect bridge 150B is embedded, and after the interconnect bridge 150B is embedded, a portion of the protective material 156 may be removed during a process of forming the recess portion R. An upper surface of the protective material 156 may be substantially coplanar with an upper surface of the first insulating layer 111 on the recess portion R. For example, the protective material 156 may be flattened during the process of forming the recess portion R. The protective material 156 may include an insulating material. As the insulating material, a thermosetting resin such as an epoxy resin, a thermoplastic resin such as polyimide, or a material in which these resins are mixed with an inorganic filler such as silica, for example, organic insulating materials such as ABF, may be used, but the present disclosure is not limited thereto. The protective material 156 may include an organic insulating material with high transparency among organic insulating materials. For example, the protective material 156 may have relatively higher transparency than the insulating material 151 or the first and second insulating layers 111 and 112. As described above, the printed circuit board 100B according to another example embodiment may cover the plurality of conductive posts 154 with the protective material 156. Accordingly, the conductive post 154 may be protected, and an effective thickness of the interconnect bridge 150B may be increased. Additionally, a flatter surface may be provided when mounting the interconnect bridge 150B. Furthermore, when the transparency of the protective material 156 is high, alignment recognition may be easier when mounting the interconnect bridge 150, and thus, precision of mounting position may be improved. Accordingly, the degree of matching may be improved when the interconnect bridge 150B is embedded.

The other contents are substantially the same as described above. Meanwhile, the structure of the printed circuit board 100B according to another example embodiment may also be applied to the printed circuit board 500A according to the above-described modified example, and a detailed description thereof will be omitted.

FIG. 13 is a cross-sectional view schematically illustrating another example of a printed circuit board.

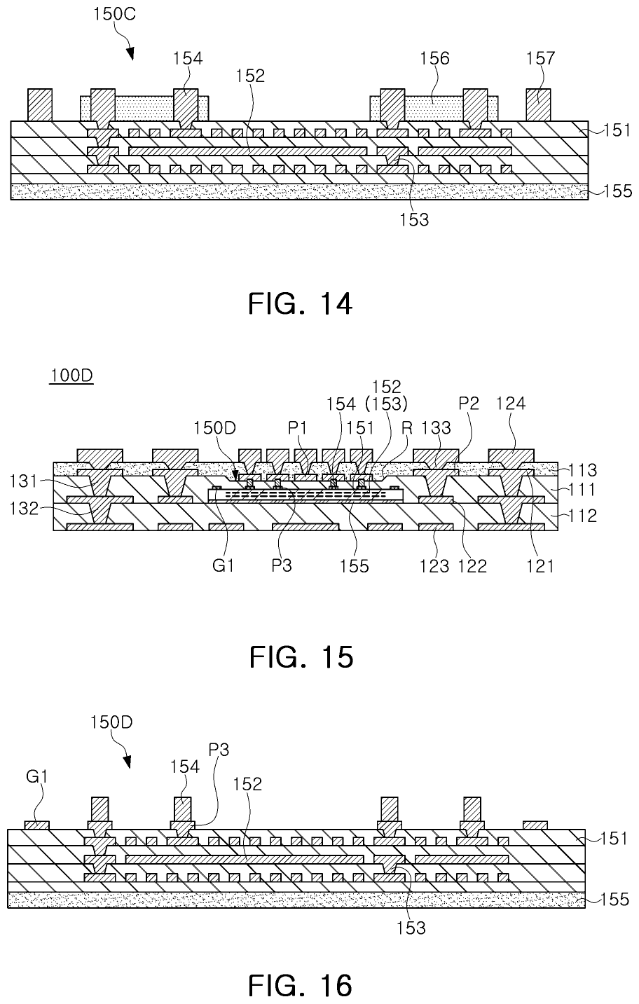

FIG. 14 is a schematic cross-sectional view of another example of an interconnect bridge.

Referring to the drawings, a printed circuit board 100C according to another example embodiment and an interconnect bridge 150C included therein according to another example embodiment may further include an alignment mark 157, in the printed circuit board 100A according to another example embodiment described above and the interconnect bridge 150B included therein according to another example embodiment. For example, the interconnect bridge 150C may further include alignment marks 157 disposed on the insulating material 151 and spaced apart from the protective material 156. The alignment mark 157 may be disposed on substantially the same level as the plurality of conductive posts 154. The alignment mark 157 may be formed of the same material when forming the plurality of conductive posts 154. For example, the alignment mark 157 may include the metal materials described above. The alignment mark 157 may be embedded in the first insulating layer 111, and if necessary, a portion of the alignment mark 157 may be exposed through the recess portion R. As described above, in the printed circuit board 100C according to another example embodiment, the interconnect bridge 150C may include the alignment mark 157. Accordingly, alignment recognition may be easier when mounting the interconnect bridge 150C, and precision of the mounting position may be improved. Accordingly, the degree of matching may be improved when the interconnect bridge 150C is embedded.

The other contents are substantially the same as described above. Meanwhile, the structure of the printed circuit board 100C according to another example embodiment may also be applied to the printed circuit board 500A according to the above-described modified example, and a detailed description thereof will be omitted.

FIG. 15 is a cross-sectional view schematically illustrating another example of a printed circuit board.

FIG. 16 is a schematic cross-sectional view of another example of an interconnect bridge.

Referring to the drawings, in a printed circuit board 100D according to another example embodiment and an interconnect bridge 150D included therein according to another example embodiment, a conductive pattern layer 152 disposed on an uppermost side, among a plurality of conductive pattern layers 152, may be disposed on an upper surface of an insulating material 151, and the conductive pattern layer 152 disposed on the uppermost side may include a conductive pad P3 connected to the conductive post 154 and a first ground pattern G1 spaced apart from the conductive post 154, in the printed circuit board 100A according to the above-described example embodiment and the interconnect bridge 150A included therein according to the example embodiment. As described above, if necessary, the conductive pad P3 for the conductive post 154 may be further formed on the insulating material 151, and the first ground pattern G1 may be further formed in the remaining space. Accordingly, the conductive post 154 may be formed more easily and higher, and more diverse designs may be possible.

The other contents are substantially the same as described above. Meanwhile, the structure of the printed circuit board 100D according to another example embodiment may also be applied to the printed circuit board 500A according to the above-described modified example, and a detailed description thereof will be omitted.

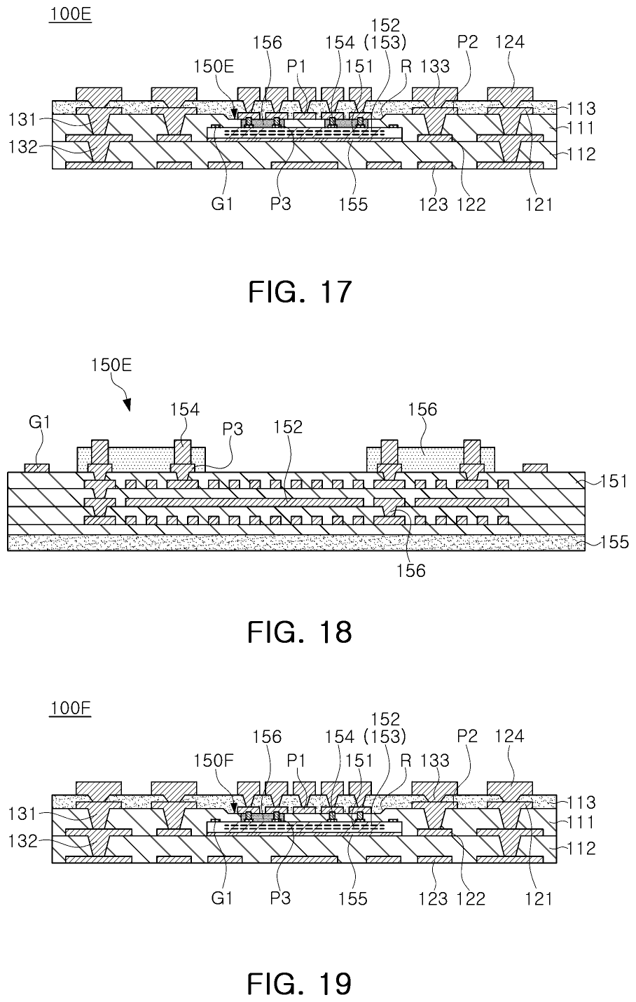

FIG. 17 is a cross-sectional view schematically illustrating another example of a printed circuit board.

FIG. 18 is a schematic cross-sectional view of another example of an interconnect bridge.

Referring to the drawings, a printed circuit board 100E according to another example embodiment and an interconnect bridge 150E included therein according to another example embodiment may further include a protective material 156, in the printed circuit board 100D according to another example described above and the interconnect bridge 150D included therein according to another example embodiment. For example, the interconnect bridge 150E may further include the protective material 156 disposed on the insulating material 151 and covering at least one of the plurality of conductive posts 154 and the conductive pad P3 connected thereto. In this manner, the printed circuit board 100E according to another example embodiment may further include the protective material 156, and thus, as described above, when the interconnect bridge 150E is embedded, various effects, such as improving the degree of matching, may be achieved.

The other contents are substantially the same as described above. Meanwhile, the structure of the printed circuit board 100E according to another example embodiment may also be applied to the printed circuit board 500A according to the above-described modified example, and a detailed description thereof will be omitted.

FIG. 19 is a schematic cross-sectional view of another example of a printed circuit board.

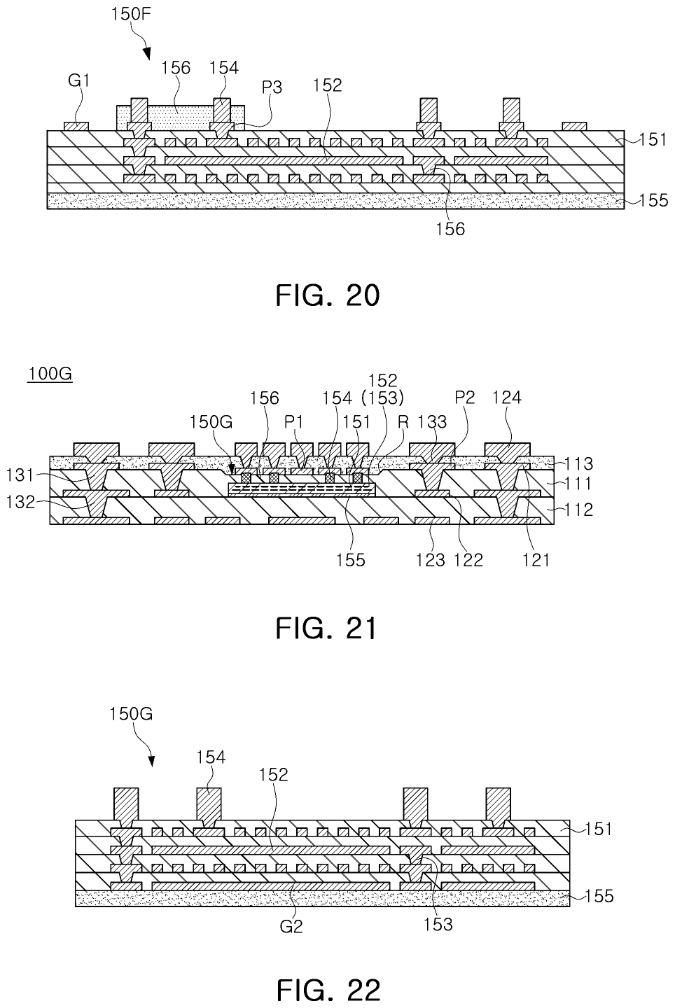

FIG. 20 is a schematic cross-sectional view of another example of an interconnect bridge.

Referring to the drawings, a printed circuit board 100F according to another example embodiment and an interconnect bridge 150F included therein according to another example embodiment may form a protective material 156 more selectively, in the printed circuit board 100E according to another example described above and the interconnect bridge 150E included therein according to another example embodiment. For example, the protective material 156 may cover some of the conductive posts 154 and some of the conductive pads P3 connected thereto. In this manner, the printed circuit board 100F according to another example embodiment may selectively form the protective material 156, through which a degree of design freedom may be further increased.

The other contents are substantially the same as described above. Meanwhile, the structure of the printed circuit board 100F according to another example embodiment may also be applied to the printed circuit board 500A according to the above-described modified example, and a detailed description thereof will be omitted.

FIG. 21 is a cross-sectional view schematically illustrating another example of a printed circuit board.

FIG. 22 is a schematic cross-sectional view of another example of an interconnect bridge.

Referring to the drawings, in a printed circuit board 100G according to another example embodiment and an interconnect bridge 150G included therein according to another example embodiment, a conductive pattern layer 152 disposed on a lowermost side, among a plurality of conductive pattern layers 152 of the interconnect bridge 150G, may be in contact with an adhesive 155, and further, the conductive pattern layer 152 disposed on the lowermost side may include a second ground pattern G2, in the printed circuit board 100A according to the above-described example embodiment and the interconnect bridge 150A included therein according to the example embodiment. For example, from a lowermost layer to an upward direction, first and third layers may be ground layers, second and fourth layers may be signal layers, and a signal connection line may not be disposed in the ground layer. In this manner, the printed circuit board 100G according to another example embodiment may implement more diverse designs.

The other contents are substantially the same as described above. Meanwhile, the structure of the printed circuit board 100G according to another example embodiment may also be applied to the printed circuit board 500A according to the above-described modified example, and a detailed description thereof will be omitted.

In the present disclosure, a thickness, a width, length, a depth, and the like, may be measured using a scanning microscope or an optical microscope based on a cross-section obtained by polishing or cutting a printed circuit board. A cut section may be a vertical section or a horizontal section, and each value may be measured based on a required cut cross-section. When the value is not constant, the value may be determined as an average value of values measured at any five random points. A width of an upper end and/or a lower end of a via or a recess portion may be measured on a cross-section in which a central axis of a substrate is cut in a thickness direction. A depth of the via or the recess portion may be measured as a distance from an upper end to a lower end of each object on a cross-section in which a central axis of each object is cut in the thickness direction of the substrate.

In the present disclosure, a pitch may be measured by capturing a cut cross-section of the printed circuit board with a scanning microscope or an optical microscope, and an average pitch may be an average value of a pitch between wirings measured at any five points. An interlayer insulation distance may also be measured by capturing the cut-cross section of the printed circuit board with a scanning microscope or an optical microscope, and an average interlayer insulation distance may be an average value of insulation distances between adjacent wirings or redistributions measured at any five points.

In the present disclosure, transparency may be measured by grinding or cutting the printed circuit board in a length or width direction to a depth in which a bridge is exposed and obtaining a cross-section, and then observing the cross-section using a scanning microscope or an optical microscope, such as an Olympus optical microscope (×1000). Alternatively, the transparency may be determined by transmittance and haze values, and the transmittance and haze may be measured with a UV-Vis Spectrometer of PerkinElmer's Lambda 1050 model. The transmittance may also be determined in a method of obtaining transmittance by identifying components through a component analysis and then recombining the components. Additionally, the transparency may also be determined through reflectance.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of approximately filling, and may include, for example, a case in which some pores or voids exist.

In the present disclosure, substantially, determination may be performed by including a process error or a positional deviation occurring in a manufacturing process, and an error during measurement. For example, being substantially coplanar may include not only a case in which components exist on the completely same plane, but also a case in which components exist on substantially the same plane. Furthermore, substantially the same material may include not only a case in which a composition and a degree of curing of a material are completely the same, but also a case in which they are substantially the same.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, a lower side, a lower portion, and a lower surface are used to refer to a downward direction with respect to a cross-section of a drawing, and an upper side, an upper portion, and an upper surface are used to refer to an opposite direction thereof. However, this defines the direction for convenience of explanation, and the scope of the rights of the claims is not particularly limited by the description of such a direction, and the concept of upper and lower portions may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
an interconnect bridge including an insulating material, a plurality of conductive pattern layers respectively disposed on or in the insulating material, and a conductive post disposed on the insulating material;
a first insulating layer embedding the interconnect bridge and having a recess portion exposing a portion of the conductive post; and
a first wiring layer disposed on the first insulating layer and including a first pad pattern connected to the exposed portion of the conductive post on the recess portion.

2. The printed circuit board according to claim 1, wherein the first wiring layer further comprises a second pad pattern disposed in a region other than the recess portion and spaced apart from the conductive post, and
an upper surface of the first pad pattern and an upper surface of the second pad pattern have a step portion from each other.

3. The printed circuit board according to claim 1, wherein one portion of the conductive post is embedded in the first insulating layer and another portion thereof protrudes from an upper surface of the first insulating layer.

4. The printed circuit board according to claim 3, wherein the first pad pattern is disposed on the upper surface of the first insulating layer on the recess portion to cover the another protruding portion of the conductive post.

5. The printed circuit board according to claim 4, wherein the first pad pattern comprises:
a first metal layer covering the upper surface of the first insulating layer and an upper surface and a side surface of the another protruding portion of the conductive post with a substantially constant thickness; and
a second metal layer disposed on the first metal layer and having an average thickness thicker than the first metal layer.

6. The printed circuit board according to claim 1, wherein the conductive post is embedded in the first insulation layer and is exposed from an upper surface of the first insulating layer so that an upper surface of the conductive post is substantially coplanar with the upper surface of the first insulating layer.

7. The printed circuit board according to claim 6, wherein the first pad pattern is disposed on the upper surface of the first insulating layer on the recess portion to cover the exposed upper surface of the conductive post.

8. The printed circuit board according to claim 7, wherein the first pad pattern comprises:
a first metal layer covering the upper surface of the first insulating layer and the exposed upper surface of the conductive post with a substantially constant thickness, and
a second metal layer disposed on the first metal layer and having an average thickness thicker than the first metal layer.

9. The printed circuit board according to claim 1, wherein the conductive post is provided in plural form,
the interconnect bridge further comprises a protective material disposed on the insulating material and covering at least one of the plurality of conductive posts, and
the protective material is disposed in a partial region on an upper surface of the insulating material.

10. The printed circuit board according to claim 9, wherein the interconnect bridge further comprises an alignment mark disposed on the insulating material and spaced apart from the protective material.

11. The printed circuit board according to claim 1, wherein a conductive pattern layer disposed on an uppermost side, among the plurality of conductive pattern layers, is disposed on an upper surface of the insulating material, and
the conductive pattern layer disposed on the uppermost side comprises a conductive pad connected to the conductive post and a first ground pattern spaced apart from the conductive post.

12. The printed circuit board according to claim 1, wherein a conductive pattern layer disposed on a lowermost side, among the plurality of conductive pattern layers, is in contact with an adhesive attached to a lower side of the interconnect bridge, and
the conductive pattern layer disposed on the lowermost side comprises a second ground pattern.

13. The printed circuit board according to claim 1, further comprising:
a second wiring layer disposed in the first insulating layer;
a first via layer penetrating through the first insulating layer and connecting the first and second wiring layers;
a second insulating layer disposed below the first insulating layer;
a third wiring layer disposed in the second insulating layer;
a second via layer penetrating through the second insulating layer and connecting the second and third wiring layers;
a third insulating layer disposed on the first insulating layer and covering the first wiring layer;
a fourth wiring layer disposed on the third insulating layer; and
a third via layer penetrating through the third insulating layer and connecting the first and fourth wiring layers,
wherein an upper surface of the third insulating layer above is substantially flat.

14. The printed circuit board according to claim 1, wherein the recess portion is tapered so that a width of an upper end thereof is larger than a width of a lower end thereof on a cross-section.

15. The printed circuit board according to claim 1, wherein the conductive post has an aspect ratio of more than 1.

16. A printed circuit board, comprising:
a first substrate unit including a plurality of first insulating layers, a plurality of first wiring layers disposed on or in the plurality of first insulating layers, and a plurality of first via layers respectively penetrating through at least one of the plurality of first insulating layers; and
a second substrate unit including a plurality of second insulation layers, a plurality of second wiring layers disposed on or in the plurality of second insulation layers, a plurality of second via layers respectively penetrating through at least one of the plurality of second insulation layers, and a plurality of conductive posts respectively disposed on a second insulation layer disposed on an uppermost side, among the plurality of second insulation layers,
wherein the second substrate unit is disposed in the first substrate unit,
at least one of the plurality of second wiring layers has a smaller average pitch than at least one of the plurality of first wiring layers, and
at least one of the plurality of first insulating layers has a step region exposing a portion of each of the plurality of conductive posts.

17. The printed circuit board according to claim 16, wherein each of the plurality of first and second insulating layers comprises an organic insulating material.

18. The printed circuit board according to claim 16, further comprising:
first and second semiconductor chips disposed on the first substrate unit and connected to each other through at least one of the plurality of second wiring layers of the second substrate unit and at least one of the plurality of conductive posts.

19. A printed circuit board, comprising:
an interconnect bridge including an insulating material, a plurality of conductive pattern layers respectively disposed on or in the insulating material, and a conductive post disposed on an upper surface of the insulating material;
a first insulating layer embedding the interconnect bridge and being in contact with at least a portion of the upper surface of the insulating material;
a first wiring layer disposed on the first insulating layer and including a first pad pattern to be in contact with the conductive post;
a second wiring layer disposed in the first insulating layer; and
a first via layer penetrating through the first insulating layer and connecting the first and second wiring layers.

20. The printed circuit board according to claim 19, wherein one portion of the conductive post is embedded in the first insulating layer and another portion thereof protrudes from an upper surface of the first insulating layer.

21. The printed circuit board according to claim 19, wherein the conductive post is embedded in the first insulation layer and is exposed from an upper surface of the first insulating layer so that an upper surface of the conductive post is substantially coplanar with the upper surface of the first insulating layer.

22. The printed circuit board according to claim 19, wherein the conductive post is provided in plural form,
the interconnect bridge further comprises a protective material disposed on the insulating material and covering at least one of the plurality of conductive posts, and
the protective material is disposed in a partial region on the upper surface of the insulating material.

23. The printed circuit board according to claim 22, wherein the interconnect bridge further comprises an alignment mark disposed on the insulating material and spaced apart from the protective material.

24. The printed circuit board according to claim 19, wherein a conductive pattern layer disposed on an uppermost side, among the plurality of conductive pattern layers, is disposed on an upper surface of the insulating material, and
the conductive pattern layer disposed on the uppermost side comprises a conductive pad connected to the conductive post.

25. The printed circuit board according to claim 24, wherein the conductive pattern layer further comprises a first ground pattern spaced apart from the conductive post.

26. The printed circuit board according to claim 19, wherein a conductive pattern layer disposed on a lowermost side, among the plurality of conductive pattern layers, is in contact with an adhesive attached to a lower side of the interconnect bridge, and
the conductive pattern layer disposed on the lowermost side comprises a second ground pattern.

27. The printed circuit board according to claim 19, further comprising:
a second insulating layer disposed below the first insulating layer;
a third wiring layer disposed in the second insulating layer;
a second via layer penetrating through the second insulating layer and connecting the second and third wiring layers;
a third insulating layer disposed on the first insulating layer and covering the first wiring layer;
a fourth wiring layer disposed on the third insulating layer; and
a third via layer penetrating through the third insulating layer and connecting the first and fourth wiring layers.
